(19) United States
(12) Patent Application Publication
(10) Pub. No.: US 2021/0321522 A1
(43) Pub. Date: Oct. 14, 2021

(54) HOUSING WITH A VENTILATION SYSTEM FOR A CONTROL DEVICE

(71) Applicant: KNORR-BREMSE SYSTEME FUER NUTZFAHRZEUGE GMBH, Muenchen (DE)

(72) Inventors: Norbert Behrendt, Stein (DE); Elena Mueller, Nuernberg (DE); Klaus Lechner, Pretzfeld (DE)

(21) Appl. No.: 16/332,572

(22) PCT Filed: Sep. 13, 2017
(86) PCT No.: PCT/EP2017/073012

§ 371 Date: Mar. 12, 2019

(30) Foreign Application Priority Data
Sep. 15, 2016 (DE) 10 2016 117 332.0

(51) Int. Cl. H05K 5/02; H05K 5/00; H05K 5/06

(52) U.S. Cl. CPC H05K 5/0213; H05K 5/069; H05K 5/0047

(57) ABSTRACT

A housing for a control device, including: a cover; a base element which is connected in a leaktight manner to the cover; and a closable opening to allow ventilation during assembly of the housing. Also described are a related brake control device, a utility vehicle, and a method.

### FIELD OF THE INVENTION

The present invention relates to a housing for a control device and, in particular, to a housing having a ventilation duct for a brake control device.

### BACKGROUND INFORMATION

Control devices, and in particular those which are used in utility vehicles, have to ensure the housing is reliably sealed off, specifically even under continuously changing external influences (temperature fluctuations, vibrations, etc.).

One problem is, for example, that excess pressure is generated in a housing comprising a cover and a base plate when the two components are connected. This occurs, in particular, when the base plate is fitted onto the cover and an airtight connection is intended to be established (for example by way of an adhesive connection). In order to equalize this excess pressure, pressure equalization elements are provided in conventional housings, said pressure equalization elements allowing the housing to be assembled without harmful excess pressure being produced. However, the pressure equalization elements also compensate for pressure fluctuations during operation, for example as a result of temperature fluctuations. By way of example, temperature fluctuations of −40° C. to 85° C. or more can occur in vehicles in the locations of the control devices, said temperature fluctuations leading to pressure fluctuations which the control devices have to withstand in order to ensure reliable functioning.

Apart from this, it is important to provide an arrangement which allows leaktightness checks for housings of control devices to be carried out in order to determine whether the housing is sufficiently leaktight and therefore suitable for use in vehicles. A leaktightness check of this kind can be achieved, for example, by forming a pressure difference between the housing interior and the housing exterior. In conventional housings, the pressure equalization elements are also used for this purpose.

These pressure equalization elements comprise, for example, a membrane which deforms in the event of a pressure difference and allows, for example, diffusion in order to establish gradual pressure equalization. However, the pressure equalization elements are additional components which make construction of the control devices more complicated and furthermore can form an additional source of faults. However, they also make manufacture of the control devices more difficult.

There is therefore a need for alternative solutions in order to firstly close off the control device in a watertight or, as far as possible, airtight manner from the surrounding area and secondly to allow simple and rapid manufacture, without pressure equalization elements being required.

### SUMMARY OF THE INVENTION

At least some of the abovementioned problems are solved by a housing as described herein, a brake control device as described herein, a utility vehicle as described herein and a method for ventilating a housing as described herein. Further descriptions herein relate to advantageous developments of the further subject matter described herein.

The present invention relates to a housing which is suitable for a control device. The housing comprises a cover, a base element which is connected to the cover in a leaktight manner, and a closable opening in order to allow ventilation during assembly of the housing. The opening can be arranged in any desired location, for example in the cover or in the base plate.

In further exemplary embodiments, the housing further comprises an electrical connection for a connection cable, wherein the opening is formed in a base region of the electrical connection in such a way that, after insertion of the electrical connection cable, the connection cable closes the closable opening.

In further exemplary embodiments, the housing comprises a closure element for the closable opening, wherein the closure element is configured in order to close the housing interior in a leaktight manner. The closure element can comprise a plug which can be inserted into the opening and closes said opening. However, the closure element can be any desired element which is suitable for closing (or else for opening) the opening. For example, said closure element can also comprise a flap or a slide. The connection cable itself can also act as a closure element if it closes the opening to a sufficient extent.

In further exemplary embodiments, the opening comprises a first section and a second section, wherein the first section has a diameter which is larger than the one diameter of the second section. The plug can also have a first region and a second region, wherein the first region has a larger diameter than the second region and can be inserted into the first section. The second region can be inserted into the second section, so that, after insertion of the plug into the opening, the plug can be inserted only as far as a predetermined depth, in order to improve the sealing effect in this way.

In further exemplary embodiments, a leaktight adhesive connection is formed between the cover and the base element, so that the housing interior is sealed off from a surrounding area in a watertight manner.

The present invention also relates to a brake control device (for example for utility vehicles) comprising a housing as has been described above. The present invention further relates to a utility vehicle comprising the brake control device.

The present invention further relates to a method for ventilating a housing of a control device during assembly. The method comprises the steps of: providing a cover and a base element, wherein the cover or the base element has an opening. The method further comprises connecting the cover and the base element, with the opening providing ventilation, and closing the opening in order to seal off the housing.

The method can optionally comprise a leaktightness check in which initially a pressure difference between an interior of the housing and a surrounding area is formed using the opening. Following this, the leaktightness of the housing can be ascertained based on a time measurement and the pressure difference formed (for example detection of a decay behavior of the pressure over time).

The opening can optionally be formed in a base region of an electrical connection of the control device and the method can optionally comprise closing the opening by inserting a plug into the opening and connecting a connection cable to the electrical connection. The connection cable blocks removal of the inserted plug.

Therefore, the present invention achieves the abovementioned technical object by way of a housing which provides a ventilation opening in the assembly process in order to equalize a pressure difference when assembling the housing. The ventilation opening also allows the leaktightness of the housing to be checked by way of forming a predetermined test pressure.

The exemplary embodiments of the present invention will be more clearly understood together with the following detailed description and the accompanying drawings of the different exemplary embodiments which, however, are not intended to be understood such that they limit the disclosure to the specific exemplary embodiments, but rather serve merely for explanation and understanding.

### BRIEF DESCRIPTION OF THE DRAWINGS

FIG. 1 shows a housing for a control device according to one exemplary embodiment of the present invention.

FIGS. 2A and 2B show further details of the housing with the plug inserted according to a further exemplary embodiment.

FIGS. 3A and 3B show an exemplary embodiment of the housing without the plug.

### DETAILED DESCRIPTION

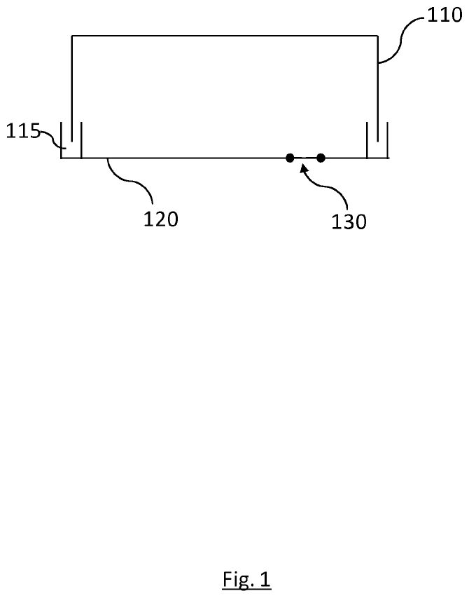

FIG. 1 shows a housing according to one exemplary embodiment of the present invention. The housing is suitable for a control device in a vehicle, in particular in a utility vehicle, and comprises a cover 110, a base element 120 (for example a base plate) and a closable opening 130 in order to allow ventilation during assembly of the housing. The cover 110 and the base element 120 are connected to one another in a leaktight (for example watertight or airtight) manner. To this end, a groove is formed in the base element 120 for example, it being possible for an end section of the cover 110 to be inserted into said groove and said end section and groove being connected to one another in a leaktight manner by an exemplary sealing arrangement (for example by an adhesive mass). The control device may be any desired control device, wherein, however, a brake control device is intended to be included in particular.

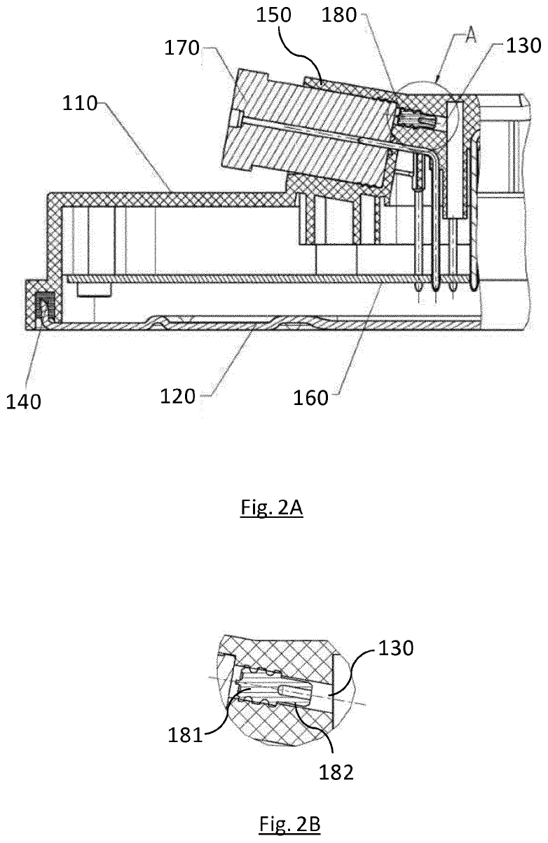

FIG. 2A shows further details of the housing which can be implemented in various exemplary embodiments of the present invention. In the exemplary embodiment shown, the groove 115 is formed in the cover 110 and an exemplary adhesive connection is formed in the groove 115 in order to achieve reliable sealing-off of the housing. The housing can exhibit an extremely wide variety of components, wherein only one printed circuit board 160, which is electrically contacted by way of a connection cable 170, is shown by way of example.

In the exemplary embodiment shown, the closable opening 130 is configured as a ventilation duct in the cover 110. The opening 130 can be configured, for example, as part of the electrical connection 150, wherein the electrical connection 150 can constitute a socket outlet (or connection socket) for the connection cable 170. For example, the opening 130 can be located in a base region and can be closable by a plug 180.

FIG. 2B shows an enlarged illustration of the region A of the housing in which the opening 130 with the plug 180 is formed. The plug 180 can be placed into the opening 130 before insertion of the connection cable 170 into the socket outlet 150 for example. The plug 180 can be formed, for example, in a conical or stepped manner, so that the plug 180 can be inserted only as far as a predetermined depth within the opening 130. The connection cable 170 prevents the plug 130 from sliding out after insertion of the connection cable 170 into the socket outlet 150. At the same time, the plug 180 cannot enter the housing interior on account of the shape of said plug itself or else on account of the shape of the opening 130. Owing to the fastening of the connection cable 170 in the electrical connection 150 (but also by a clamping or screw connection or other types of locking for example), it is optionally likewise possible for the plug 180 to be held in the opening 130 under prestress and therefore for said opening to be closed in a leaktight manner and remain closed.

The plug 180 comprises, for example, a relatively thin section 182 which can be positioned in a deeper-lying region of the opening 130 (region with the relatively small cross-sectional area). In addition, the plug 180 comprises annular projections which are formed in that region of the plug 180 which, after insertion, faces the outer region of the housing. The annular projections are, for example, configured to be somewhat larger than a cross-sectional area of the relatively wide section of the opening 130, so that the plug 180 is pressed into the opening 130 with application of minimal force in order to thereby ensure reliable leaktightness.

According to the present invention, the closable opening 130 can be open (the plug 180 is not yet inserted) during manufacture of the housing. Therefore, the opening 130 provides ventilation and prevents a pressure difference in relation to the surrounding area being produced during assembly, specifically even when the adhesive connection 140 connects the base element 120 to the cover 110 in an airtight manner. The resulting excess pressure can be immediately discharged via the ventilation duct 130 when the base element 120 is joined to the cover 110.

After manufacture, the housing is closed off in an airtight manner in which the opening 130 of the housing is closed by the plug 180 (for example a dummy plug). Reliable positioning of the dummy plug 180 can be ensured, as mentioned, by virtue of the opening 130 being provided, for example, as part of a connection socket 150, so that, after the cabling 170 is fitted, the plug 180 is blocked and cannot leave the opening 130. The use of a dummy plug 180 has the advantage that cost-effective standard parts can be used in order to ensure the housing is sealed off. In addition, positioning the opening 130 as part of an electrical connection 150 is a reliable way of ensuring the dummy plug is likewise positioned securely after, by way of example, a cable harness plug is latched in.

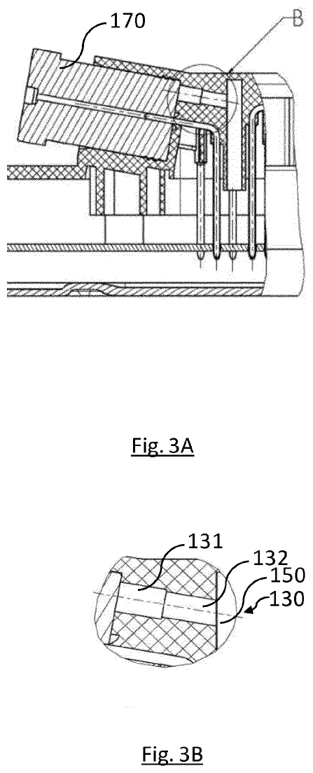

FIG. 3A shows an exemplary embodiment of the housing, in which the opening 130 is not closed by a plug 180. The closable opening 130 still provides a ventilation duct during assembly, but closure is not performed by the connection cable 170 alone.

FIG. 3B shows an enlarged illustration of the region B of the housing, in which the opening 130 is configured without the plug 180. In the exemplary embodiment shown, the opening 130 is of a stepped configuration and comprises a first section 131 with a relatively large cross-sectional area and a second section 312 with a relatively small cross-sectional area, wherein the first section 130 with the relatively large cross-sectional area is located in the region in which the connection cable 170 is inserted into the connection socket 150.

Owing to the stepped cross-sectional configuration of the opening 130, it is therefore possible for the above-described plug 180, which can likewise be formed in a stepped manner, to be placed into the opening 130 and to reliably close the opening 130 at the step. The optional plug 180 does not need to be inserted, particularly when the connection cable 170 can likewise provide reliable sealing off (as in FIGS. 3A, 3B).

The opening 130, in the manner in which it is formed in the housing in accordance with the present invention, can also be used for checking leaktightness. To this end, a pressure difference in relation to the surrounding area can be deliberately established via the opening 130, for example before insertion of the plug 180 or the connection cable 170. When the pressure difference is maintained (on its own) over a specific period of time, this shows that the housing is sufficiently leaktight. It is likewise possible to ascertain the leaktightness based on a time measurement (for achieving the pressure difference or a subsequent pressure drop).

A further advantage of exemplary embodiments is that, in contrast to conventional housings, no pressure equalization elements are required since the opening 130 to allow ventilation during assembly. Pressure equalization during operation (for example as a result of temperature fluctuations) can be achieved, for example, by deformation of the base element 120.

The features of the invention which are disclosed in the description, the claims and the figures can be essential to the implementation of the invention both individually and in any combination.

### THE LIST OF REFERENCE SYMBOLS IS AS FOLLOWS

110 Cover
120 Base element
130 Opening
131, 132 Sections of the opening
140 Connection
150 Electrical connection
160 Printed circuit board
170 Connection cable
180 Plug
181,182 Regions of the plug

1-11. (canceled)

12. A housing for a control device, comprising:
a cover;
a base element which is connected in a leaktight manner to the cover; and
a closable opening to allow ventilation during assembly of the housing.

13. The housing of claim 12, further comprising:
an electrical connection for a connection cable;
wherein the opening is formed in a base region of the electrical connection so that, after insertion of the electrical connection cable, the connection cable closes the closable opening.

14. The housing of claim 12, further comprising:
a closure element for the closable opening, wherein the closure element is configured to close the housing interior in a leaktight manner.

15. The housing of claim 14, wherein the closure element includes a plug which is insertable into the opening and closes the opening.

16. The housing of claim 12, wherein the opening has a first section and a second section, wherein the first section has a diameter which is larger than a diameter of the second section, and wherein the plug has a first region and a second region, wherein the first region has a larger diameter than the second region and is insertable into the first section, and the second region is insertable into the second section, so that, after insertion of the plug into the opening, the plug is insertable only as far as a predetermined depth, so as to improve the sealing effect.

17. The housing of claim 12, wherein a leaktight adhesive connection is formed between the cover and the base element, so that the housing interior is sealed off from a surrounding area in a watertight manner.

18. A brake control device, comprising:
a housing, including:
a cover;
a base element which is connected in a leaktight manner to the cover; and
a closable opening to allow ventilation during assembly of the housing.

19. A utility vehicle, comprising:
a brake control device having a housing, the housing including:
a cover;
a base element which is connected in a leaktight manner to the cover; and
a closable opening to allow ventilation during assembly of the housing.

20. A method for ventilating a housing of a control device during assembly, the method comprising:
providing a cover and a base element, wherein the cover or the base element has an opening;
connecting the cover and the base element with the opening, so as to provide ventilation; and
closing the opening to seal off the housing.

21. The method of claim 20, wherein the opening is formed in a base region of an electrical connection of the control device, wherein a closing of the opening includes inserting a plug into the opening and connecting a connection cable to the electrical connection, and wherein the connection cable blocks removal of the inserted plug.

22. The method of claim 20, further comprising:
forming a pressure difference between an interior of the housing and a surrounding area using the opening; and
establishing a leaktightness of the housing based on a time measurement and the pressure difference.
